(19) United States
(12) Patent Application Publication
(10) Pub. No.: US 2025/0383780 A1
(43) Pub. Date: Dec. 18, 2025

(54) INDEPENDENT SOURCE CLOCKS FOR MEMORY ACCESS OPERATIONS

(71) Applicant: Micron Technology, Inc., Boise, ID (US)

(72) Inventors: Deping He, Boise, ID (US); Caixia Yang, Boise, ID (US); Liang Yu, Boise, ID (US)

(21) Appl. No.: 19/233,604

(22) Filed: Jun. 10, 2025

Related U.S. Application Data
(60) Provisional application No. 63/660,314, filed on Jun. 14, 2024.

(51) Int. Cl. G06F 3/06

(52) U.S. Cl. CPC G06F 3/0613; G06F 3/0659; G06F 3/0679

(57) ABSTRACT

Methods, systems, and devices for independent source clocks for memory access operations are described. A memory system may be configured to support a multi-source clock scheme that utilizes independent source clocks for read data transfers and write data transfers across an interface. Based on performing the read operations, the memory system may communicate read data over a channel using a first source clock operating at a first frequency. The memory system may communicate write data over the channel using a second source clock operating at a second frequency. Based on communicating the write data, the memory system may perform one or more write operations.

### CROSS REFERENCE

The present application for patent claims priority to U.S. Patent Application No. 63/660,314 by He et al., entitled “INDEPENDENT SOURCE CLOCKS FOR MEMORY ACCESS OPERATIONS,” filed Jun. 14, 2024, which is assigned to the assignee hereof, and which is expressly incorporated by reference in its entirety herein.

### TECHNICAL FIELD

The following relates to one or more systems for memory, including independent source clocks for memory access operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports independent source clocks for memory access operations in accordance with examples as disclosed herein.

FIG. 2 shows an example of a system that supports independent source clocks for memory access operations in accordance with examples as disclosed herein.

FIG. 3 shows an example of clock schemes that support independent source clocks for memory access operations in accordance with examples as disclosed herein.

FIG. 4 shows a block diagram of a memory system that supports independent source clocks for memory access operations in accordance with examples as disclosed herein.

FIG. 5 shows a flowchart illustrating a method or methods that support independent source clocks for memory access operations in accordance with examples as disclosed herein.

### DETAILED DESCRIPTION

Some memory systems (e.g., universal flash storage (USF) devices, not-AND (NAND) systems, or other storage devices) may support data communication with other systems (e.g., host systems) across an interface (e.g., including one or more open NAND flash interface (ONFI) channels). To support a relatively faster memory access speeds (e.g., for artificial intelligence (AI) related applications or other applications that utilize relatively high data transfer speeds), memory systems may support a relatively faster source clock (e.g., a relatively higher source clock frequency) associated with transferring data across the interface (e.g., a relatively faster data transfer rate). Additionally, some memory systems may utilize a single source clock to transfer both read data and write data across the interface (e.g., transferring data over the ONFI channel(s)). However, a relatively higher source clock frequency (e.g., a faster data transfer rate) may not provide a same performance benefit for both read data transfers and write data transfers. For instance, the memory system may perform write operations at a rate that is relatively slower than read operations (e.g., and slower than the source clock data transfer rate). Thus, by using a single source clock, the memory system may receive write data faster than the memory system is capable of performing the corresponding write operations, resulting in additional power consumption at the memory system (e.g., without a significant performance benefit), among other adverse effects.

In accordance with one or more techniques described herein, a memory system may be configured to support a multi-source clock scheme that utilizes independent source clocks for read data transfers (e.g., transmitting read data) and write data transfers (e.g., receiving write data) across an interface (e.g., one or more ONFI channels). For example, the memory system may perform one or more read operations and may communicate (e.g., transmit, send, signal, convey) the corresponding read data over a channel using a first source clock operating at a first frequency. The memory system may communicate (e.g., receive, obtain, be signaled with) write data over the channel using a second source clock (e.g., different than the first source clock) operating at a second frequency and may perform one or more write operations based on receiving the write data. In some examples, the source clock for write data transfers may operate at a relatively lower frequency than the source clock for read data transfers. For example, the write data source clock speed may be controlled to match a write performance metric (e.g., NAND program time), which may be different from (e.g., slower than) a read performance metric (e.g., NAND read time). Additionally, the memory system may receive the independent source clocks from an external system (e.g., a host system). Accordingly, the memory system may receive write data using a relatively slower source clock (e.g., relative to a source clock for read data transfers) thereby improving energy efficiency and power savings while maintaining a performance expectation associated with write operations.

In addition to applicability in memory systems as described herein, techniques for independent source clocks for memory access operations may be generally implemented to improve the performance of various electronic devices and systems (including AI applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by balancing improvements to memory access speeds with improved energy conservation, which may sustainably support decreased processing or latency times, improved response times, or otherwise improved user experience, among other benefits.

Features of the disclosure are illustrated and described in the context of systems, devices, and circuits. Features of the disclosure are further illustrated and described in the context of clock schemes and flowcharts.

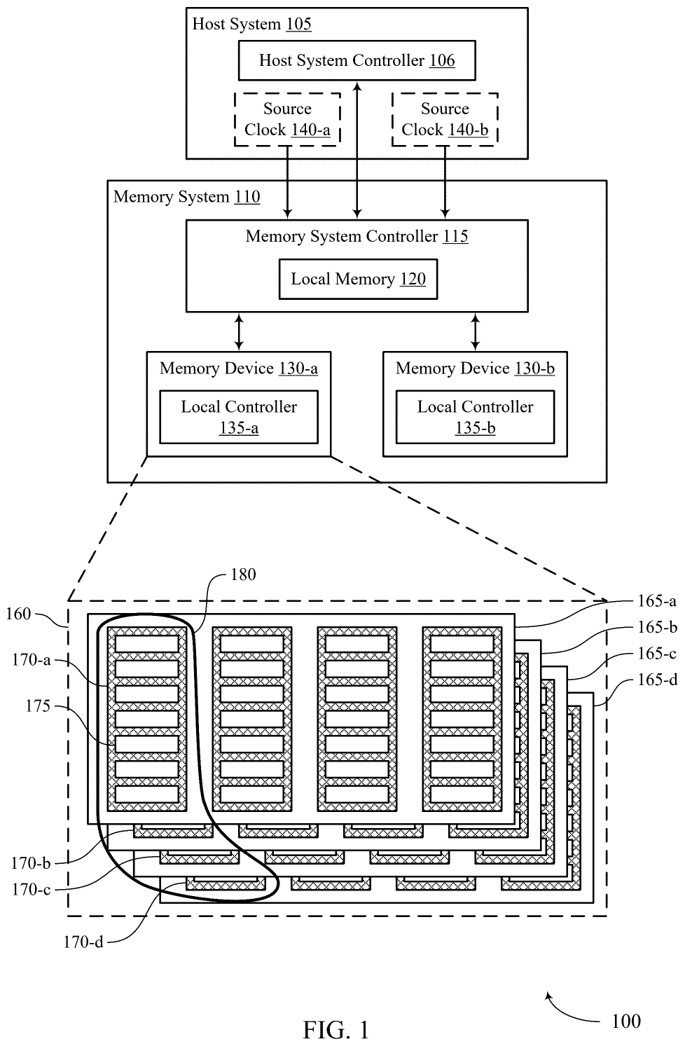

FIG. 1 shows an example of a system 100 that supports independent source clocks for memory access operations in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (e.g., ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

Some memory systems 110 may support data communication with host systems 105 across a channel (e.g., a NAND ONFI channel). For example, some memory systems 110 may utilize a single source clock 140 for both read data transfers and write data transfers across the interface (e.g., an interface or channel between the memory system 110 and the host system). However, a frequency for the single source clock 140 may not provide a same performance benefit for read data operations and write data operations (e.g., may not be optimized for both reads and writes). For instance, write operations may satisfy a performance expectation with a reduced clock speed relative to a clock speed used for read operations. Thus, using a single source clock 140 for both read data transfers and write data transfers may result in increased power consumption (e.g., and increased manufacturing costs) for the system 100, among other adverse effects.

In accordance with one or more techniques described herein, a memory system 110 (e.g., a memory system controller 115) may be configured to support multiple source clocks 140 (e.g., a source clock 140-a and a source clock 140-b) for read data transfers (e.g., transmitting read data across the ONFI channel) and write data transfers (e.g., receiving write data across the ONFI channel). For example, the memory system 110 may perform one or more read operations and may communicate (e.g., transmit) the corresponding read data over a channel using a source clock 140-a operating at a first frequency. The memory system 110 may also perform write operations by communicating (e.g., receiving) write data over the channel using a source clock 140-b that operates at a second frequency that is lower than the first frequency of the source clock 140-a. As depicted by the non-limiting example of the system 100, the memory system 110 may receive the source clock 140-a and the source clock 140-b from the host system 105. Additionally, or alternatively, the source clock 140-a and/or the source clock 140-b may be located within the memory system 110 (e.g., generated internally by the memory system 110). Accordingly, the memory system 110 may be enabled to balance performance expectations with power savings, which may improve efficiency of the system 100.

The system 100 may include any quantity of non-transitory computer readable media that support independent source clocks for memory access operations. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

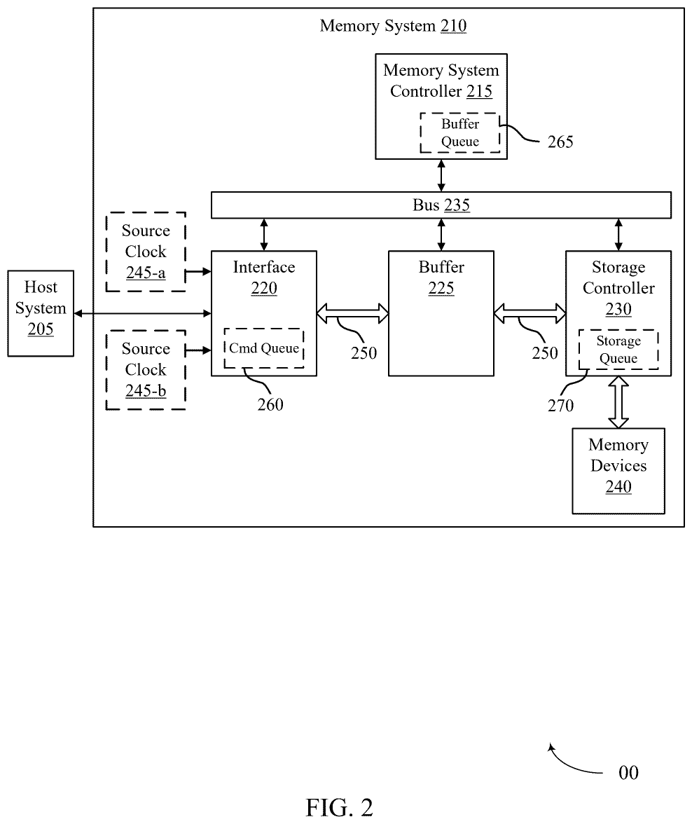

FIG. 2 shows an example of a system 200 that supports independent source clocks for memory access operations in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240 directly or via a bus (not shown), which may include using a protocol specific to each type of memory device 240. In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

After the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

Some memory systems 210 may support data communication with host systems 205 via a channel (e.g., a NAND ONFI channel). For example, the memory system 210 may utilize the interface 220 to communicate information (e.g., read commands, write commands, read data, write data, or other signaling) to the host system 205 over the channel. Some memory systems 210 may utilize a single source clock 245 for both read data transfers and write data transfers across the channel. However, a frequency for the single source clock 245 may not provide a same performance benefit for read data operations and write data operations (e.g., may not be optimized for both reads and writes). For instance, write operations may satisfy a performance expectation with a reduced clock speed relative to a clock speed used for read operations. Thus, using a single source clock 245 for both read data transfers and write data transfers may result in increased power consumption (e.g., and increased manufacturing costs) for the system 200, among other adverse effects.

In accordance with one or more techniques described herein, a memory system 210 (e.g., a memory system controller 215) may be configured to support multiple source clocks 245 (e.g., a source clock 245-a and a source clock 245-b) for read data transfers (e.g., across an ONFI channel) and write data transfers (e.g., across the ONFI channel). For example, the memory system 210 may perform one or more read operations and may communicate (e.g., transmit) the corresponding read data over a channel using a source clock 245-a operating at a first frequency. The memory system 210 may also perform write operations by communicating (e.g., receiving) write data over the channel using a source clock 245-b that operates at a second frequency that is lower than the first frequency of the source clock 245-a. In some examples, the memory system 210 may receive the source clock 245-a and/or the source clock 245-b from the host system 205 or may independently generate the source clock 245-a and the source clock 245-b. Accordingly, the memory system 210 may be enabled to balance performance expectations with power savings, which may improve efficiency of the system 100.

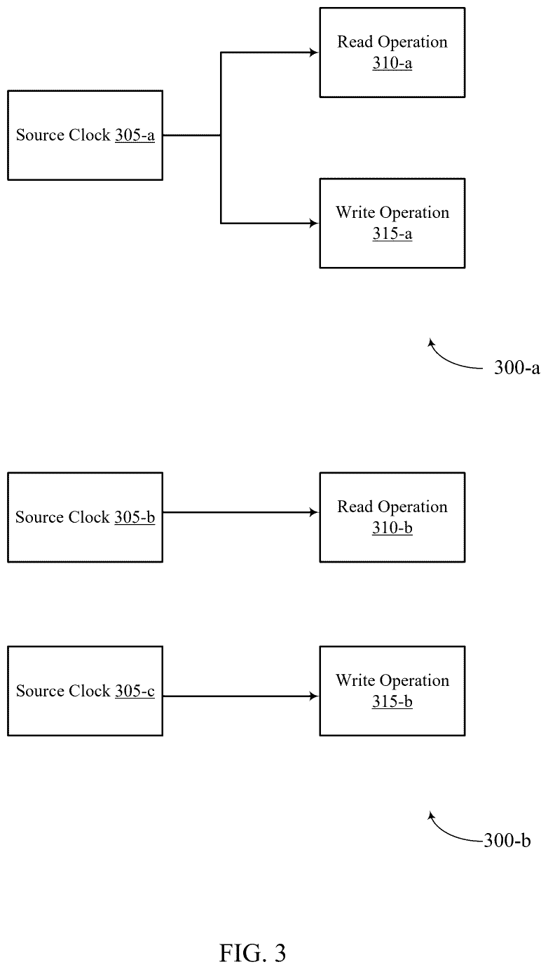

FIG. 3 shows an example of clock schemes 300 that support independent source clocks for memory access operations in accordance with examples as disclosed herein. The clock schemes 300 may be examples of clock schemes utilized by one or more devices described herein, such as a memory system 110, a memory system 210, a host system 105, a host system 205, or some other device as described with reference to FIGS. 1 and 2. The clock scheme 300-a may be an example of a single clock scheme that utilizes a source clock 305-a for both read operations 310-a and write operations 315-a. The clock scheme 300-b may be an example of a multi-clock scheme (e.g., an independent source clock scheme) that utilizes a source clock 305-b for read operations 310-b and a source clock 305-c for write operations 315-b (e.g., at a memory system 110 or a memory system 210).

In some cases, memory systems (e.g., and host systems) may be expected to support increased data transfer rates (e.g., to improve memory system performance, to support AI applications or other data-intensive applications). A “data transfer rate” may refer to a speed at which data is transferred from one device (e.g., or system) to another. Data transfer rates may be measured in megatransfers per second (MT/s) (e.g., a measure of a quantity of data transfer operations that occur in one second) or megabytes per second (MB/s) (e.g., a measure of a quantity of data that can be transferred in one second). Such speed increases may be realized by increasing a frequency of a source clock 305 (e.g., an ONFI source clock) associated with communicating data across an interface (e.g., one or more communication channel, an ONFI channel, or some path used for data transfer between devices or systems). In some cases, a “source clock” may refer to a timing signal that is used to synchronize data transfer between devices (e.g., or systems) across one or more channels. For instance, a source clock 305 may provide a sequence of digital pulses (e.g., at a constant rate), and data may be transferred across the one or more channels based on the rising and/or falling edge of the pulses. As a non-limiting example, a host system may operate at a first data transfer rate (e.g., a first speed, 9800 MB/s). Accordingly, a source clock 305 may support a data transfer rate that supports (e.g., meets an end-to-end performance for) the host data transfer rate (e.g., 3600 MT/s or greater for a four flash channel controller), which may be associated with relatively high controller driver capability and increased cost in order to meet signal integrity.

In some cases, different types of operations may be associated with different durations to perform the operation. For instance, a write duration (e.g., a write duration defined by a memory standard, NAND program time (tProg), about 300 microseconds (μs) for TLC and 50 us for SLC) for a write operation may be relatively slower than a read duration (e.g., a read duration defined by a memory standard, NAND read time (tRead), 30 us for TLC and 20 us for SLC) for a read operation. Some systems may utilize the clock scheme 300-a which supports a single source clock 305-a that drives both read operations 310-a and write operations 315-a. However, using the same source clock 305-a may not be efficient for both read operations 310-a and write operations 315-a. That is, a frequency of the source clock 305-a may be increased to support relatively faster data transfer rates (e.g., increased to 1800 MHZ), but the increased speed may increase power consumption with little performance benefit for some operations (e.g., a faster ONFI may be over-qualified for write operations 315-a).

For instance, a relatively faster data transfer rate (e.g., 1800 MHZ clock frequency supporting 3600 MT/s ONFI speed) may match a read duration expectation (e.g., tRead) for a read operation 310-a relatively well (e.g., within a tolerance threshold, in case of 4 plane NAND). That is, the memory system may be able to process read operations at a relatively similar rate (e.g., tRead) as the read data transfer rate (e.g., the ONFI speed) However, a write operation may satisfy a write duration expectation (e.g., tProg, in case of 4 plane NAND) for write operations 315-a at a rate that matches a relatively slower data transfer rate (e.g., less than 3600 MT/s ONFI speed, such as 2400 MT/s or 1800 MT/s). In other words, if a relatively faster data transfer rate is used for write operations 315-a, write data may be communicated across a channel faster than the memory system is able to process the write operations 315-a. Accordingly, increasing a data transfer rate for a source clock 305-a that is utilized for both read operations 310-a and write operations 315-a (e.g., in the clock scheme 300-a) may be associated with increased power consumption (e.g., relatively higher write peak power proportional to ONFI speed) and increased cost (e.g., increased ASIC cost) without providing a significant performance benefit (e.g., at least for write operations 315-a).

In accordance with one or more techniques described herein, a memory system (e.g., a memory system 110, a memory system 210) may be configured to operate in accordance the clock scheme 300-b that utilizes different source clocks 305 for respective operations. For example, a memory system may utilize a source clock 305-b for read operations 310-b and a source clock 305-c for write operations 315-b. In other words, different clock domains may be utilized for read operations 310-b and write operations 315-b respectively. In some examples, the source clock 305-b and the source clock 305-c may be received from (e.g., provided by) an external system (e.g., such as a host system 105 or host system 205) or may be internally generated by the memory system.

In some examples, the memory system (e.g., a controller of the memory system, processing circuitry of the memory system) may receive (e.g., be provided with) the source clock 305-b from a host system. The memory system may also receive the source clock 305-c from the host system. In some examples, the source clock 305-b may correspond to a first ONFI source clock and the source clock 305-c may correspond to a second ONFI source clock. The source clock 305-b may operate at a first frequency (e.g., a relatively faster frequency, 1800 MHZ) and the source clock 305-c may operate at a second frequency (e.g., different than the first frequency, a relatively slower frequency, 1200 MHZ, 900 MHZ). In some examples, the first frequency associated with the source clock 305-b may be higher than the second frequency associated with the source clock 305-c, which may improve performance of read operations 310-b while reducing power consumption for write operations 315-b.

The memory system may receive a read command from a host system and may perform one or more read operations 310-b (e.g., may retrieve data from one or more memory cells). After performing the read operation(s) 310-b, the memory system may transmit the data corresponding to the read operation 310-b (e.g., first data, data associated with a read command) to the host system. The memory system may communicate (e.g., transmit, indicate, convey) the read data over a channel (e.g., an ONFI channel) using the source clock 305-b operating at the first frequency (e.g., 1800 MHZ). That is, the memory system may transmit the read data based on the receiving (e.g., in accordance with) the source clock 305-b.

The memory system may receive (e.g., obtain) a write command from the host system, and may receive write data (e.g., second data, data associated with the write command) based on (e.g., in response to) receiving the write command. The memory system may communicate (e.g., receive) the write data over a channel (e.g., an ONFI channel, a different ONFI channel than is used for transmitting the read data) using the source clock 305-c operating at the second frequency (e.g., a frequency that is less than the first frequency). That is, the memory system may receive the write data based on receiving (e.g., in accordance with) the source clock 305-c. The memory system may perform one or more write operations 315-b (e.g., may program one or more memory cells to store the received data) based on (e.g., in response to) receiving the write command and receiving the write data.

In some examples, the memory system may receive, based on using the source clock 305-c, the write data in accordance with a duration (e.g., 40 μs) that less than or equal to a write duration associated with a performance of the one or more write operations 315-b (e.g., tProg, 50-300 μs). In other words, a duration to transfer write date (e.g., about 40 μs) may be shorter than an expected time to perform a corresponding write operation (e.g., about 50-300 μs). Accordingly, a frequency for the source clock 305-c may be adjusted (e.g., further reduced) to match the write duration time. Such adjustments may be based on a type of operation (e.g., a type of write operation), a type of cell being written to (e.g., such as SLC or TLC), a write duration metric satisfying, or failing to satisfy, a threshold, or other workload conditions. For example, the memory system may receive another write command associated with different write data (e.g., third write data, associated with programming a different type of cell, such as TLC) and may perform one or more second write operations 315-b based on (e.g., in response to) receiving the command and the data (e.g., the third data). In such examples, the memory system may receive the write data over a channel (e.g., an ONFI channel) using a source clock 305-c operating at a third frequency that is lower than the second frequency. That is, the write source clock frequency may be tuned (e.g., further reduced) to match a write duration (e.g., NAND tProg) at the memory system (e.g., given that a write duration metric at the memory system satisfies a threshold).

Accordingly, by supporting the clock scheme 300-b a memory system may be enabled to balance satisfying performance expectations (e.g., for tRead and tProg) and power efficiency improvements. That is, the memory system may support a relatively faster data transfer rate for performance of read operations 310-b, while maintaining a relatively slower data transfer rate for performance of write operations 315-b, thus satisfying both read operation performance and write operation performance and also reducing power consumption.

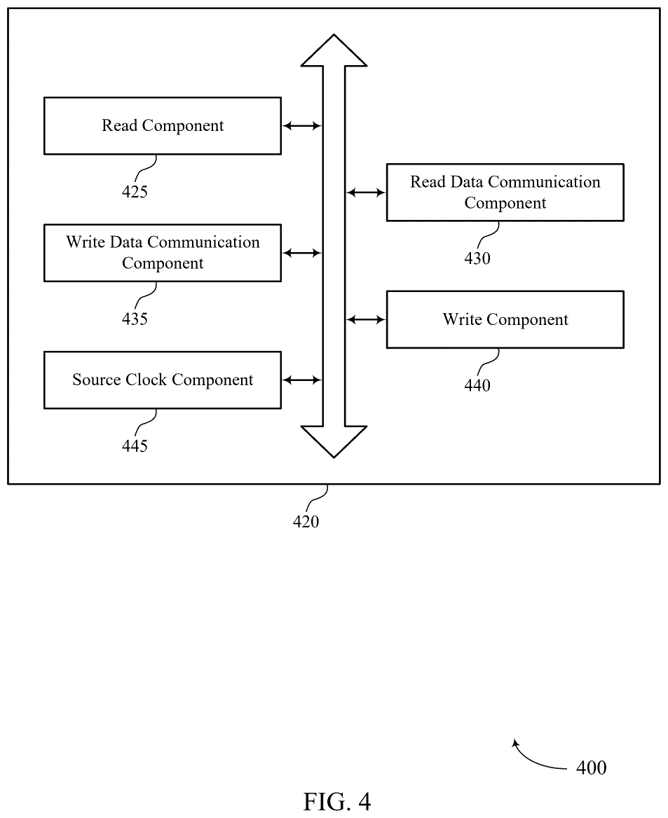

FIG. 4 shows a block diagram 400 of a memory system 420 that supports independent source clocks for memory access operations in accordance with examples as disclosed herein. The memory system 420 may be an example of aspects of a memory system as described with reference to FIGS. 1 through 3. The memory system 420, or various components thereof, may be an example of means for performing various aspects of independent source clocks for memory access operations as described herein. For example, the memory system 420 may include a read component 425, a read data communication component 430, a write data communication component 435, a write component 440, a source clock component 445, or any combination thereof. Each of these components, or components of subcomponents thereof (e.g., one or more processors, one or more memories), may communicate, directly or indirectly, with one another (e.g., via one or more buses).

The read component 425 may be configured as or otherwise support a means for performing one or more read operations. The read data communication component 430 may be configured as or otherwise support a means for transmitting first data associated with a read command over a channel in response to performing the one or more read operations, the first data communicated over the channel using a first source clock operating at a first frequency. The write data communication component 435 may be configured as or otherwise support a means for receiving second data associated with a write command over the channel, the second data communicated over the channel using a second source clock operating at a second frequency. The write component 440 may be configured as or otherwise support a means for performing one or more write operations in response to receiving the second data.

In some examples, the source clock component 445 may be configured as or otherwise support a means for receiving the first source clock from a host system, where transmitting the first data is in response to receiving the first source clock. In some examples, the source clock component 445 may be configured as or otherwise support a means for receiving the second source clock from the host system, where receiving the second data is in response to receiving the second source clock.

In some examples, the first frequency associated with the first source clock is higher than the second frequency associated with the second source clock.

In some examples, to support receiving the second data, the write data communication component 435 may be configured as or otherwise support a means for receiving, in accordance with using the second source clock, the second data in accordance with a duration that less than or equal to a write duration associated with performing the one or more write operations.

In some examples, the first source clock corresponds to a first ONFI source clock. In some examples, the second source clock corresponds to a second ONFI source clock.

In some examples, the write data communication component 435 may be configured as or otherwise support a means for receiving third data associated with a second write command over the channel, the third data communicated over the channel using a third source clock operating at a third frequency that is lower than the second frequency. In some examples, the write component 440 may be configured as or otherwise support a means for performing one or more second write operations in response to receiving the third data.

In some examples, the read data communication component 430 may be configured as or otherwise support a means for receiving the read command from a host system, where transmitting the first data is in response to receiving the read command.

In some examples, the write data communication component 435 may be configured as or otherwise support a means for receiving the write command from a host system, where receiving the second data is in response to receiving the write command.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

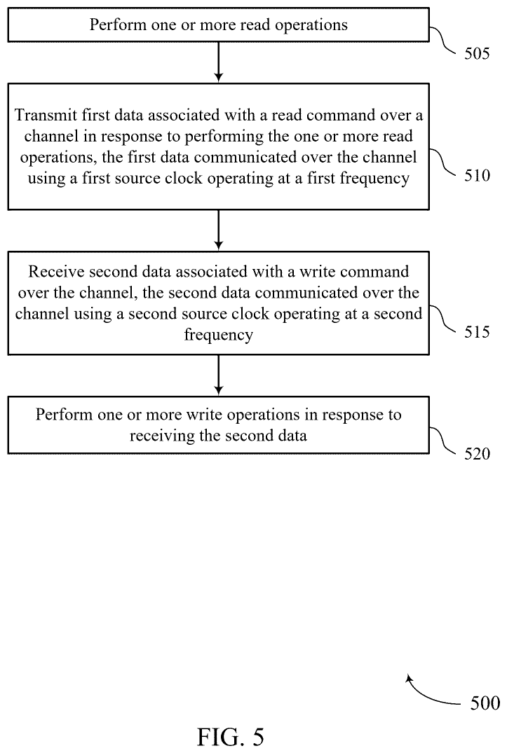

FIG. 5 shows a flowchart illustrating a method 500 that supports independent source clocks for memory access operations in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include performing one or more read operations. In some examples, aspects of the operations of 505 may be performed by a read component 425 as described with reference to FIG. 4.

At 510, the method may include transmitting first data associated with a read command over a channel in response to performing the one or more read operations, the first data communicated over the channel using a first source clock operating at a first frequency. In some examples, aspects of the operations of 510 may be performed by a read data communication component 430 as described with reference to FIG. 4.

At 515, the method may include receiving second data associated with a write command over the channel, the second data communicated over the channel using a second source clock operating at a second frequency. In some examples, aspects of the operations of 515 may be performed by a write data communication component 435 as described with reference to FIG. 4.

At 520, the method may include performing one or more write operations in response to receiving the second data. In some examples, aspects of the operations of 520 may be performed by a write component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing one or more read operations; transmitting first data associated with a read command over a channel in response to performing the one or more read operations, the first data communicated over the channel using a first source clock operating at a first frequency; receiving second data associated with a write command over the channel, the second data communicated over the channel using a second source clock operating at a second frequency; and performing one or more write operations in response to receiving the second data.

Aspect 2: The method, apparatus, or non-transitory computer-readable medium of aspect 1, further including operations, features, circuitry, logic, means, or instructions, or any combination thereof for receiving the first source clock from a host system, where transmitting the first data is in response to receiving the first source clock and receiving the second source clock from the host system, where receiving the second data is in response to receiving the second source clock.

Aspect 3: The method, apparatus, or non-transitory computer-readable medium of any of aspects 1 through 2, where the first frequency associated with the first source clock is higher than the second frequency associated with the second source clock.

Aspect 4: The method, apparatus, or non-transitory computer-readable medium of any of aspects 1 through 3, where receiving the second data includes operations, features, circuitry, logic, means, or instructions, or any combination thereof for receiving, in accordance with using the second source clock, the second data in accordance with a duration that less than or equal to a write duration associated with performing the one or more write operations.

Aspect 5: The method, apparatus, or non-transitory computer-readable medium of any of aspects 1 through 4, where the first source clock corresponds to a first ONFI source clock and the second source clock corresponds to a second ONFI source clock.

Aspect 6: The method, apparatus, or non-transitory computer-readable medium of any of aspects 1 through 5, further including operations, features, circuitry, logic, means, or instructions, or any combination thereof for receiving third data associated with a second write command over the channel, the third data communicated over the channel using a third source clock operating at a third frequency that is lower than the second frequency and performing one or more second write operations in response to receiving the third data.

Aspect 7: The method, apparatus, or non-transitory computer-readable medium of any of aspects 1 through 6, further including operations, features, circuitry, logic, means, or instructions, or any combination thereof for receiving the read command from a host system, where transmitting the first data is in response to receiving the read command.

Aspect 8: The method, apparatus, or non-transitory computer-readable medium of any of aspects 1 through 7, further including operations, features, circuitry, logic, means, or instructions, or any combination thereof for receiving the write command from a host system, where receiving the second data is in response to receiving the write command.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
perform one or more read operations;
transmit first data associated with a read command over a channel in response to performing the one or more read operations, the first data communicated over the channel using a first source clock operating at a first frequency;
receive second data associated with a write command over the channel, the second data communicated over the channel using a second source clock operating at a second frequency; and
perform one or more write operations in response to receiving the second data.

2. The memory system of claim 1, wherein the processing circuitry is further configured to cause the memory system to:
receive the first source clock from a host system, wherein transmitting the first data is in response to receiving the first source clock; and
receive the second source clock from the host system, wherein receiving the second data is in response to receiving the second source clock.

3. The memory system of claim 1, wherein the first frequency associated with the first source clock is higher than the second frequency associated with the second source clock.

4. The memory system of claim 1, wherein receiving the second data comprises the processing circuitry configured to cause the memory system to:
receive, in accordance with using the second source clock, the second data in accordance with a duration that less than or equal to a write duration associated with performing the one or more write operations.

5. The memory system of claim 1, wherein:
the first source clock corresponds to a first open NAND flash interface (ONFI) source clock; and
the second source clock corresponds to a second ONFI source clock.

6. The memory system of claim 1, wherein the processing circuitry is further configured to cause the memory system to:
receive third data associated with a second write command over the channel, the third data communicated over the channel using a third source clock operating at a third frequency that is lower than the second frequency; and
perform one or more second write operations in response to receiving the third data.

7. The memory system of claim 1, wherein the processing circuitry is further configured to cause the memory system to:
receive the read command from a host system, wherein transmitting the first data is in response to receiving the read command.

8. The memory system of claim 1, wherein the processing circuitry is further configured to cause the memory system to:
receive the write command from a host system, wherein receiving the second data is in response to receiving the write command.

9. A non-transitory computer-readable medium storing code comprising instructions which, when executed by one or more processors of a memory system, cause the memory system to:
perform one or more read operations;
transmit first data associated with a read command over a channel in response to performing the one or more read operations, the first data communicated over the channel using a first source clock operating at a first frequency;
receive second data associated with a write command over the channel, the second data communicated over the channel using a second source clock operating at a second frequency; and
perform one or more write operations in response to receiving the second data.

10. The non-transitory computer-readable medium of claim 9, wherein the instructions, when executed by the one or more processors of the memory system, further cause the memory system to:
receive the first source clock from a host system, wherein transmitting the first data is in response to receiving the first source clock; and
receive the second source clock from the host system, wherein receiving the second data is in response to receiving the second source clock.

11. The non-transitory computer-readable medium of claim 9, wherein the first frequency associated with the first source clock is higher than the second frequency associated with the second source clock.

12. The non-transitory computer-readable medium of claim 9, wherein the instructions to receive the second data, when executed by the one or more processors of the memory system, further cause the memory system to:
receive, in accordance with using the second source clock, the second data in accordance with a duration that less than or equal to a write duration associated with performing the one or more write operations.

13. The non-transitory computer-readable medium of claim 9, wherein:
the first source clock corresponds to a first open NAND flash interface (ONFI) source clock; and
the second source clock corresponds to a second ONFI source clock.

14. The non-transitory computer-readable medium of claim 9, wherein the instructions, when executed by the one or more processors of the memory system, further cause the memory system to:
receive third data associated with a second write command over the channel, the third data communicated over the channel using a third source clock operating at a third frequency that is lower than the second frequency; and
perform one or more second write operations in response to receiving the third data.

15. The non-transitory computer-readable medium of claim 9, wherein the instructions, when executed by the one or more processors of the memory system, further cause the memory system to:
receive the read command from a host system, wherein transmitting the first data is in response to receiving the read command.

16. The non-transitory computer-readable medium of claim 9, wherein the instructions, when executed by the one or more processors of the memory system, further cause the memory system to:
receive the write command from a host system, wherein receiving the second data is in response to receiving the write command.

17. A method at a memory system, comprising:
performing one or more read operations;
transmitting first data associated with a read command over a channel in response to performing the one or more read operations, the first data communicated over the channel using a first source clock operating at a first frequency;
receiving second data associated with a write command over the channel, the second data communicated over the channel using a second source clock operating at a second frequency; and
performing one or more write operations in response to receiving the second data.

18. The method of claim 17, further comprising:
receiving the first source clock from a host system, wherein transmitting the first data is in response to receiving the first source clock; and
receiving the second source clock from the host system, wherein receiving the second data is in response to receiving the second source clock.

19. The method of claim 17, wherein the first frequency associated with the first source clock is higher than the second frequency associated with the second source clock.

20. The method of claim 17, wherein receiving the second data comprises:
receiving, in accordance with using the second source clock, the second data in accordance with a duration that less than or equal to a write duration associated with performing the one or more write operations.

21. The method of claim 17, wherein:
the first source clock corresponds to a first open NAND flash interface (ONFI) source clock; and
the second source clock corresponds to a second ONFI source clock.

22. The method of claim 17, further comprising:
receiving third data associated with a second write command over the channel, the third data communicated over the channel using a third source clock operating at a third frequency that is lower than the second frequency; and
performing one or more second write operations in response to receiving the third data.
